(19) United States
(12) Patent Application Publication
(10) Pub. No.: US 2016/0181537 A1
(43) Pub. Date: Jun. 23, 2016

(54) Electroluminescence Device

(71) Applicant: MERCK PATENT GMBH, Darmstadt (DE)

(72) Inventors: Junyou Pan, Frankfurt Am Main (DE); Frank Egon Meyer, Kronberg (DE)

(73) Assignee: Merck Patent GmbH, Darmstadt (DE)

(21) Appl. No.: 14/908,202

(22) PCT Filed: Jul. 1, 2014
(86) PCT No.: PCT/EP2014/001803

§ 371 Date: Jan. 28, 2016

(30) Foreign Application Priority Data
Jul. 29, 2013 (EP) 13003772.4

(51) Int. Cl. H01L 51/00; C09K 11/06; C08G 61/12

(52) U.S. Cl. CPC H01L 51/0039; C08G 61/128; H01L 51/0043; C09K 11/06; H01L 51/0037; H01L 51/5072

(57) ABSTRACT

The present application relates to an electroluminescence device containing a) an anode, b) a cathode, c) at least one emitter layer containing at least one electroluminescent material and arranged between the anode and the cathode, and d) at least one electron transport layer containing at least one material having electron-conducting or predominantly electron-conducting properties and arranged between the at least one emitter layer and the cathode, said device being characterized in that the at least one emitter layer contains a polymer having hole-conducting or predominantly hole-conducting properties. The electroluminescence device according to the invention is distinguished by a high lifetime and a high radiation efficiency.

The present invention relates to an electroluminescent device comprising a polymer having hole-conducting or predominantly hole-conducting properties in the emitter layer.

In a number of different applications which can be attributed to the electronics industry in the broadest sense, the use of organic semiconductors as functional materials has been reality for some time or is expected in the near future.

For instance, light-sensitive organic materials (e.g. phthalocyanines) and organic charge transport materials (e.g. triarylamine-based hole transporters) have already been used for several years in photocopiers.

Some specific semiconductive organic compounds, some of which are also capable of emitting light in the visible spectral region, are now already being used in commercially available devices, for example in organic electroluminescent devices.

The individual components thereof, organic light-emitting diodes (OLEDs), have a very broad spectrum of application. OLEDs are already finding use, for example, as:
white or colored backlighting for monochrome or multicolor display elements (for example in pocket calculators, mobile phones and other portable applications),
large-area displays (for example as traffic signs or posters),
lighting elements in a wide variety of different colors and forms,
monochrome or full-color passive matrix displays for portable applications (for example for mobile phones, PDAs and camcorders), full-color large-area and high-resolution active matrix displays for a wide variety of different applications (for example for mobile phones, PDAs, laptops and televisions).

Development in some of these applications is already very advanced. There is nevertheless still a great need for technical improvements.

The operative lifetime of OLEDs is generally still comparatively low. In the case of full-color applications in particular (full-color displays, i.e. displays which have no segmentation but can represent all colors over the entire area), this leads to different speeds of aging of the individual colors. The result of this is that, even before the end of the actual lifetime of the display (which is generally defined by a drop to 50% of the starting brightness), there is a distinct shift in the white point, meaning that the color rendering of the representation in the display becomes very poor. In order to avoid this problem, some display users define the lifetime as being the 70% or 90% lifetime (i.e. drop in the starting brightness to 70% or to 90% of the starting value). However, the effect of this is that the lifetime is even shorter.

The efficiencies of OLEDs are acceptable, but improvements are of course still also desired here, specifically for portable applications.

The color coordinates of OLEDs, specifically of broadband white-emitting OLEDs, consisting of all three base colors, are not yet good enough for many applications. Particularly the combination of good color coordinates with high efficiency is still in need of improvement.

The abovementioned reasons are necessitating improvements in the production of OLEDs.

The general structure of organic electroluminescent devices is described, for example, in U.S. Pat. No. 4,539,507 and EP 1202358 A. Typically, an organic electroluminescent device consists of several layers which are applied one on top of another by means of vacuum methods or different printing methods, especially solution-based printing methods such as inkjet printing, or solvent-free printing methods such as thermal transfer printing or LITI (laser-induced thermal imaging).

A typical OLED processed mainly from solution, i.e. using soluble materials, generally has the following layers:
a carrier plate or substrate, preferably made from glass or from plastic;
a transparent anode, preferably composed of indium tin oxide (“ITO”);
at least one hole injection layer (“HIL”), for example based on conductive polymers having hole conductor properties, for example polyaniline (PANI) or polythiophene derivatives (such as PEDOT);
optionally an interlayer (“IL”) or a hole transport layer (“HTL”), for example based on polymers containing triarylamine units (WO 2004/084260 A);
at least one emission layer (“EML”), this layer interacting partly with the layers mentioned above and below; an EML preferably includes fluorescent dyes, for example N,N′-diphenylquinacridone (QA), or phosphorescent dyes, for example tris(phenylpyridyl)iridium (Ir(PPy)₃) or tris(2-benzothiophenylpyridyl)iridium (Ir(BTP)₃), and doped matrix materials, for example 4,4′-bis(carbazol-9-yl)biphenyl (CBP). An EML may also consist of polymers, mixtures of polymers, mixtures of polymers with low molecular weight compounds or mixtures of different low molecular weight compounds;
optionally a hole blocking layer (“HBL”), where this layer may partly be combined with the ETL or EIL layers mentioned hereinafter; an HBL preferably comprises materials which have a low-lying HOMO and block the transport of holes, for example BCP (2,9-dimethyl-4,7-diphenyl-1,10-phenanthroline or bathocuproin) or bis(2-methyl-8-quinolinolato)-4-(phenylphenolato)aluminum(III) (BAlq);
optionally an electron transport layer (“ETL”) which may consist, for example, of aluminum tris-8-hydroxyquinoxalinate (AlQ₃);
optionally an electron injection layer (“EIL”) which may partly be combined with the aforementioned EML, HBL or ETL layers or a small portion of the cathode is specially treated or specially deposited; where this EIL layer may be a thin layer consisting of a material having a high dielectric constant, for example a layer of LiF, Li₂O, BaF₂, MgO or NaF;
a cathode, preference being given here to using metals, combinations of metals or metal alloys having a low work function, for example Ca, Ba, Cs, Mg, Al, In or Mg/Ag.

Individual layers such as HBL, ETL and/or EIL layers can, if required, rather than by application from solution, also be produced by vapor deposition under reduced pressure, producing what are called hybrid devices.

The whole device is appropriately (according to the application) structured, contact-connected and finally customarily also hermetically sealed, since the lifetime of such devices can be severely shortened in the presence of water and/or air. The same also applies to what are called inverted structures where the light is emitted from the cathode, called top emission. In the case of inverted OLEDs, the anode is formed, for example, from Al/Ni/NiOx or from Al/Pt/PtOx or from other metal/metal oxide combinations having a work function greater than 5 eV. The cathode is formed from the same materials described further up, although the metal or metal alloy is applied very thinly and is thus transparent. The layer thickness is preferably below 50 nm, more preferably below 30 nm and most preferably below 10 nm, a proportion of the light emitted always being absorbed as a result. A further transparent material, for example ITO or IZO (“indium zinc oxide”), may also be applied to this transparent cathode.

Conventional OLEDs have at least the following layer structure: anode/hole injection layer/emitter layer/cathode. In structures of this type, the recombination of the electrons with the holes and hence the generation of radiation takes place in the emitter layer. Holes migrate into the emitter layer which, as well as the emitter molecules, typically comprises at least one predominantly electron-conducting material, and recombine therein with excitation of the emitter molecules by the electrons. Most of the polymers used nowadays in OLEDs have a higher mobility for electrons than for holes (cf. Friend et al. in Nature, Vol. 434, pp. 194).

Predominantly hole-conducting conjugated electroluminescent polymer materials have not been described to date and have not been used to date in emitter layers either. The use of these materials in emitter layers, as well as the simple mode of production of the layer, would also give a crucial improvement in the possible options and enable the construction of novel OLEDs.

WO 2008/034758 A discloses an OLED having a relatively long lifetime which comprises a light-emitting layer comprising a phosphorescent emitter and comprising a hole-conducting material. An electron-conducting layer is disposed between the light-emitting layer and cathode. This document describes mainly hole-conducting materials consisting of small organic molecules. Hole-conducting polymers have also been described, but only polyvinylcarbazole, PEDOT or PANI are disclosed. PEDOT and PANI are materials which have to be doped with protic acids to achieve sufficient hole conductivity. Materials of this kind are unsuitable for emitter layers since the presence of protons prevents or at least has a significant negative impact on light emission. Polyvinylcarbazole is a polymer having a saturated main hydrocarbon chain in which the conductivity-imparting carbazole groups are arranged in the side chains. Electrically conductive polymers of this kind are only of limited stability.

WO 2006/076092 A discloses phosphorescent OLEDs having an exciton-blocking layer. The emitter layer used therein comprises, as well as the light-emitting material, a hole-conducting material and an electron-conducting material. The only emitter layers disclosed are formed from small organic molecules. Nor are any emitter layers having predominantly hole-conducting properties disclosed, but only emitter layers having predominantly electron-conducting properties.

WO 2005/112147 A discloses an organic light-emitting diode having improved lifetime. This is achieved by the presence of a layer of an arylborane copolymer between the cathode and emitter layer and/or between the anode and emitter layer. No details of the structure of the light-emitting diode or as to the configuration of the emitter layer or further layers are disclosed.

It has now been found that, surprisingly, the combination of an emitter layer comprising a predominantly hole-conducting polymer which does not contain any protic acids as dopants with an electron-conducting layer which comprises a predominantly electron-conducting material and is disposed between the cathode and emitter layer leads to OLEDs having a distinctly improved lifetime. The result of this structure is that the electron/hole pairs recombine in the hole-conducting emitter layer and induce the emitter molecules present therein to emit light.

According to the invention, it is also possible to combine two or more layer pairs of this kind.

It is thus an object of the present invention to provide an electroluminescent device which has a long lifetime combined with high light yield and enables the use of emitter layers that have not been used to date.

It is a further object of the present invention to provide a novel light-emitting material which can be induced to radiate by the recombination of electron-hole pairs.

Yet a further object of the present invention is that of providing an electroluminescent device having a simple structure, which features a long lifetime and a high light yield.

Furthermore, the device of the invention is to be easy to produce, be capable of broad-band emission and have high radiation efficiency.

The present invention thus provides an electroluminescent device comprising
a) an anode,
b) a cathode,
c) at least one emitter layer which comprises at least one emitter and is disposed between the anode and the cathode, and
d) at least one electron transport layer which comprises at least one material having electron-conducting or predominantly electron-conducting properties and is disposed between the at least one emitter layer and the cathode,
   which is characterized in that the at least one emitter layer comprises at least one polymer, preferably a polymer having hole-conducting or predominantly hole-conducting properties.

In the context of the present application, a polymer having hole-conducting or predominantly hole-conducting properties is understood to mean a polymer which can either conduct exclusively holes or which can conduct both holes and electrons. However, the mobility of the holes in this polymer has to be at least one order of magnitude, preferably at least two and more preferably at least three orders of magnitude higher than the mobility of the electrons.

The hole mobility of the polymers used in accordance with the invention having predominantly hole-conducting properties at 25° C. is preferably at least 10⁴ cm²N/V*sec, measured by the time-of-flight method at an electrical field strength of 5*10⁷ V/m. This electrical field strength corresponds to an OLED having layer thickness 80 nm and 4 V.

If the polymer used in accordance with the invention having predominantly hole-conducting properties is also capable of conducting electrons, the electron mobility at 25° C. is preferably at most 10⁻⁵ cm²/V*sec, measured by the time-of-flight method at an electrical field strength of 5*10⁷ V/m.

The electroluminescent device of the invention can of course also be operated at other electrical field strengths, for example at field strengths in the range from 10′ to 10¹⁰ V/m.

The mobility of free charge carriers in polymers can be determined by various methods known to those skilled in the art. For the purposes of the present application, the time-of-flight method is used (see: “Organic Photoreceptors for Xerography”, Paul M. Borsenberger, 1998, Marcel Dekker).

In the context of the present application, a material having electron-conducting or predominantly electron-conducting properties is understood to mean a material which can conduct exclusively electrons or which can conduct both holes and electrons. However, the mobility of the electrons in this material has to be at least one order of magnitude, preferably at least two and more preferably at least three orders of magnitude higher than the mobility of the holes. These materials may be low molecular weight organic compounds, polymers or a mixture of polymers with low molecular weight organic compounds, preference being given to polymers. However, it is also possible to use mixtures of different polymers and/or of different low molecular weight organic compounds. In addition, it is possible to use copolymers having both hole-conducting and electron-conducting structural units.

In principle, it is possible to use any emitter known to those skilled in the art as emitter in the emitter layer of the device of the invention.

In a preferred embodiment, the emitter is incorporated into a polymer as repeat unit, more preferably into the polymer having hole-conducting or predominantly hole-conducting properties.

In a further preferred embodiment, the emitter is mixed into a matrix material which may be a small molecule, a polymer, an oligomer, a dendrimer or a mixture thereof.

Preference is given to an emitter layer comprising at least one emitter selected from fluorescent and phosphorescent compounds.

The expression “emitter unit” or “emitter” refers here to a unit or compound where radiative decay with emission of light occurs on acceptance of an exciton or formation of an exciton.

There are two emitter classes: fluorescent and phosphorescent emitters. The expression “fluorescent emitter” relates to materials or compounds which undergo a radiative transition from an excited singlet state to its ground state. The expression “phosphorescent emitter” as used in the present application relates to luminescent materials or compounds containing transition metals. These typically include materials where the emission of light is caused by spin-forbidden transition(s), for example transitions from excited triplet and/or quintuplet states.

According to quantum mechanics, the transition from excited states having high spin multiplicity, for example from excited triplet state, to the ground state is forbidden. However, the presence of a heavy atom, for example of iridium, osmium, platinum or europium, ensures strong spin-orbit coupling, meaning that the excited singlet and triplet become mixed, and so the triplet gains a certain singlet character, and luminance can be efficient when the singlet-triplet mixture leads to a rate of radiative decay faster than the non-radiative event. This mode of emission can be achieved with metal complexes, as reported by Baldo et al. in Nature 395, 151-154 (1998).

Particular preference is given to an emitter selected from the group of the fluorescent emitters.

Many examples of fluorescent emitters have already been published, for example styrylamine derivatives as disclosed, for example, in JP 2913116 B and in WO 2001/021729 A1, and indenofluorene derivatives as disclosed, for example in WO 2008/006449 and WO 2007/140847 A.

The fluorescent emitters are preferably polyaromatic compounds, for example 9,10-di(2-naphthylanthracene) and other anthracene derivatives, derivatives of tetracene, xanthene, perylene, for example 2,5,8,11-tetra-t-butylperylene, phenylene, e.g. 4,4′-(bis(9-ethyl-3-carbazovinylene)-1,1′-biphenyl, fluorene, arylpyrenes (US 2006/0222886), arylenevinylenes (U.S. Pat. No. 5,121,029, U.S. Pat. No. 5,130,603), derivatives of rubrene, coumarin, rhodamine, quinacridone, for example N,N′-dimethylquinacridone (DMQA), dicyanomethylenepyran, for example 4-(dicyanoethylene)-6-(4-dimethylaminostyryl-2-methyl)-4H-pyran (DCM), thiopyrans, polymethine, pyrylium and thiapyrylium salts, periflanthene, indenoperylene, bis(azinyl)imine-boron compounds (US 2007/0092753 A1), bis(azinyl)methane compounds and carbostyryl compounds.

Further preferred fluorescent emitters are described in C. H. Chen et al.: “Recent developments in organic electroluminescent materials” Macromol. Symp. 125, (1997), 1-48 and “Recent progress of molecular organic electroluminescent materials and devices” Mat. Sci. and Eng. R, 39 (2002), 143-222.

Further preferred fluorescent emitters are selected from the class of the monostyrylamines, the distyrylamines, the tristyrylamines, the tetrastyrylamines, the styrylphosphines, the styryl ethers and the arylamines.

A monostyrylamine is understood to mean a compound containing one substituted or unsubstituted styryl group and at least one preferably aromatic amine. A distyrylamine is understood to mean a compound containing two substituted or unsubstituted styryl groups and at least one preferably aromatic amine. A tristyrylamine is understood to mean a compound containing three substituted or unsubstituted styryl groups and at least one preferably aromatic amine. A tetrastyrylamine is understood to mean a compound containing four substituted or unsubstituted styryl groups and at least one preferably aromatic amine. The styryl groups are more preferably stilbenes which may also have further substitution. The corresponding phosphines and ethers are defined analogously to the amines. For the purposes of the present application, an arylamine or an aromatic amine is understood to mean a compound containing three substituted or unsubstituted aromatic or heteroaromatic ring systems bonded directly to the nitrogen. At least one of these aromatic or heteroaromatic ring systems is preferably a fused ring system preferably having at least 14 aromatic ring atoms. Preferred examples of these are aromatic anthracenamines, aromatic anthracenediamines, aromatic pyrenamines, aromatic pyrenediamines, aromatic chrysenamines and aromatic chrysenediamines. An aromatic anthracenamine is understood to mean a compound in which one diarylamino group is bonded directly to an anthracene group, preferably in the 9 position. An aromatic anthracenediamine is understood to mean a compound in which two diarylamino groups are bonded directly to an anthracene group, preferably in the 9,10 positions. Aromatic pyrenamines, pyrenediamines, chrysenamines and chrysenediamines are defined analogously thereto, where the diarylamino groups in the pyrene are bonded preferably in the 1 position or in 1,6 positions.

Further preferred fluorescent emitters are selected from indenofluorenamines and indenofluorenediamines, for example according to WO 2006/122630, benzoindenofluorenamines and benzoindenofluorenediamines, for example according to WO 2008/006449, and dibenzoindenofluorenamines and dibenzoindenofluorenediamines, for example according to WO 2007/140847.

Examples of emitters from the class of the styrylamines are substituted or unsubstituted tristilbenamines or the dopants described in WO 2006/000388, WO 2006/058737, WO 2006/000389, WO 2007/065549 and WO 2007/115610. Distyrylbenzene and distyrylbiphenyl derivatives are described in U.S. Pat. No. 5,121,029. Further styrylamines can be found in US 2007/0122656 A1.

Particularly preferred styrylamine emitters and triarylamine emitters are the compounds of the formulae (1) to (6), as disclosed in U.S. Pat. No. 7,250,532 B2, DE 102005058557 A1, CN 1583691 A, JP 08053397 A, U.S. Pat. No. 6,251,531 B1 and US 2006/210830 A.

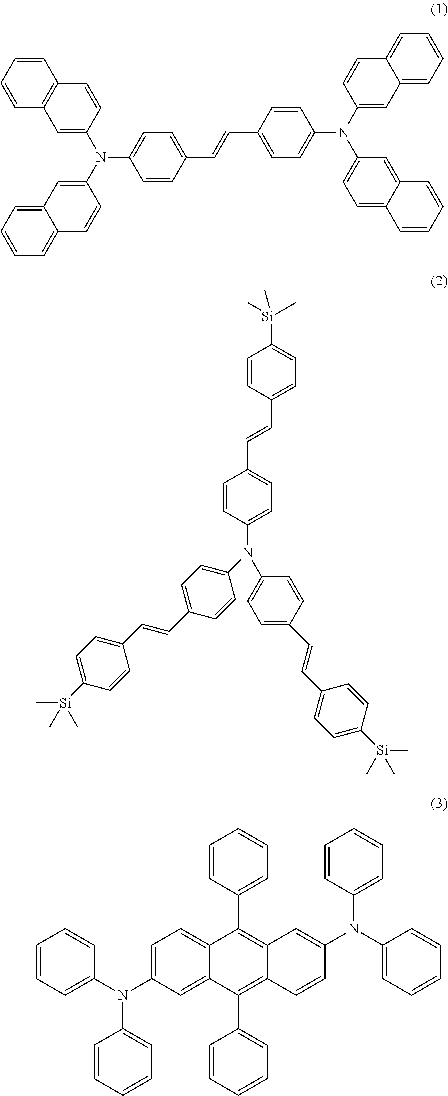

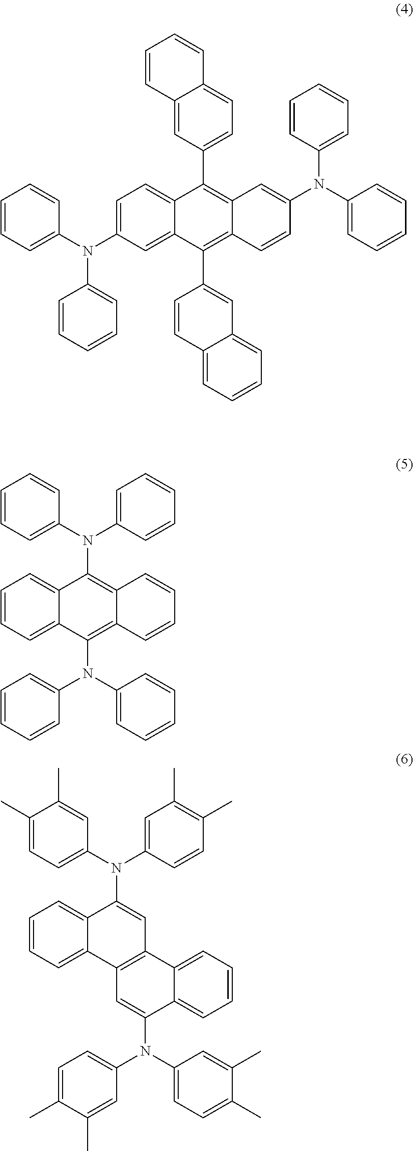

Further preferred fluorescent emitters are selected from the group of the triarylamines, as disclosed, for example, in EP 1957606 A1 and US 2008/0113101 A1.

Further preferred fluorescent emitters are selected from the derivatives of naphthalene, anthracene, tetracene, fluorene, periflanthene, indenoperylene, phenanthrene, perylene (US 2007/0252517 A1), pyrene, chrysene, decacyclene, coronene, tetraphenylcyclopentadiene, pentaphenylcyclopentadiene, fluorene, spirofluorene, rubrene, coumarin (U.S. Pat. No. 4,769,292, U.S. Pat. No. 6,020,078, US 2007/0252517 A1), pyran, oxazone, benzoxazole, benzothiazole, benzimidazole, pyrazine, cinnamic esters, diketopyrrolopyrrole, acridone and quinacridone (US 2007/0252517 A1).

Among the anthracene compounds, 9,10-substituted anthracenes, for example 9,10-diphenylanthracene and 9,10-bis(phenylethynyl)anthracene, are particularly preferred. 1,4-Bis(9′-ethynylanthracenyl)benzene is also a preferred dopant.

Particular preference is given to one emitter in the emitter layer selected from the group of the blue-fluorescing, green-fluorescing and yellow-fluorescing emitters.

Particular preference is likewise given to one emitter in the emitter layer selected from the group of the red-fluorescing emitters. A particularly preferred red-fluorescing emitter is selected from the group of the perylene derivatives, for example of the formula (7), as disclosed, for example, in US 2007/0104977 A1:

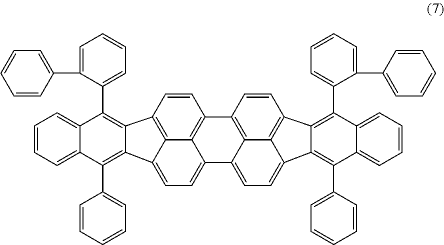 [SMILES: c1ccc(-c2ccccc2-c2c3c(c(-c4ccccc4)c4ccccc24)-c2ccc4c5ccc6c7c(ccc(c8ccc-3c2c48)c75)-c2c-6c(-c3ccccc3)c3ccccc3c2-c2ccccc2-c2ccccc2)cc1]

Particular preference is likewise given to an emitter in the emitter layer selected from the group of the phosphorescent emitters.

Examples of phosphorescent emitters are disclosed in WO 00/070655, WO 01/041512, WO 02/002714, WO 02/015645, EP 1191613, EP 1191612, EP 1191614 and WO 2005/033244.

In general, all phosphorescent complexes as used according to the prior art and as known to those skilled in the art in the field of organic electroluminescence are suitable, and the person skilled in the art will be able to use further phosphorescent complexes without exercising inventive skill.

The phosphorescent emitter may be a metal complex, preferably of the formula M(L)_{z} in which M is a metal atom, L independently at each instance is an organic ligand bonded or coordinated to M via one, two or more positions, and z is an integer >1, preferably 1, 2, 3, 4, 5 or 6, and in which these groups are optionally joined to a polymer via one or more, preferably one, two or three, positions, preferably via the ligands L.

M is preferably a metal atom selected from transition metals, preferably from transition metals of group VIII, lanthanides and actinides, more preferably from Rh, Os, Ir, Pt, Pd, Au, Sm, Eu, Gd, Tb, Dy, Re, Cu, Zn, W, Mo, Pd, Ag and Ru and most preferably from Os, Ir, Ru, Rh, Re, Pd and Pt. M may also be Zn.

Preferred ligands are 2-phenylpyridine derivatives, 7,8-benzoquinoline derivatives, 2-(2-thienyl)pyridine derivatives, 2-(1-naphthyl)pyridine derivatives or 2-phenylquinoline derivatives. These compounds may each be substituted, for example by fluorine or trifluoromethyl substituents for blue. Secondary ligands are preferably acetylacetonate or picric acid.

Suitable complexes with particular preference are those of Pt or Pd with tetradentate ligands of the formula (8), as disclosed, for example, in US 2007/0087219 A1, in which R¹ to R¹⁴ and Z¹ to Z⁵ are as defined in US 2007/0087219 A1, Pt-porphyrin complexes having an enlarged ring system (US 2009/0061681 A1) and Ir complexes, for example 2,3,7,8,12,13,17,18-octaethyl-21H,23H-porphyrin-Pt(III), tetraphenyl-Pt(II)-tetrabenzoporphyrin (US 2009/0061681 A1), cis-bis(2-phenylpyridinato-N,C2′)Pt(II), cis-bis(2-(2′-thienyl)pyridinato-N,C3′)Pt(II), cis-bis(2-(2′-thienyl)quinolinato-N,C5)Pt(III), (2-(4,6-difluorophenyl)pyridinato-N,C2′)Pt(III) acetylacetonate or tris(2-phenylpyridinato-N,C2′)Ir(III) (Ir(ppy)₃, green), bis(2-phenylpyridinato-N,C2)Ir(III) acetylacetonate (Ir(ppy)₂ acetylacetonate, green, US 2001/0053462 A1, Baldo, Thompson et al. Nature 403, (2000), 750-753), bis(1-phenylisoquinolinato-N,C2′)(2-phenylpyridinato-N,C2′)iridium(II), bis(2-phenylpyridinato-N,C2′)(1-phenylisoquinolinato-N,C2′)iridium(III), bis(2-(2′-benzothienyl)pyridinato-N,C3′)iridium(III) acetylacetonate, bis(2-(4′,6′-difluorophenyl)pyridinato-N,C2′)iridium(III) picolinate (Firpic, blue), bis(2-(4′,6′-difluorophenyl)pyridinato-N,C2′)Ir(III) tetrakis(1-pyrazolyl)borate, tris(2-(biphenyl-3-yl)-4-tert-butylpyridine)iridium(III), (ppz)₂Ir(5phdpym) (US 2009/0061681 A1), (45ooppz)₂Ir(5phdpym) (US 2009/0061681 A1), derivatives of 2-phenylpyridine-Ir complexes, for example iridium(III) bis(2-phenylquinolyl-N,C2) acetylacetonate (PQIr), tris(2-phenylisoquinolinato-N,C)Ir(II) (red), bis(2-(2′-benzo[4,5-a]thienyl)pyridinato-N,C3)Ir acetylacetonate ([Btp2Ir(acac)], red, Adachi et al. Appl. Phys. Lett. 78 (2001), 1622-1624).

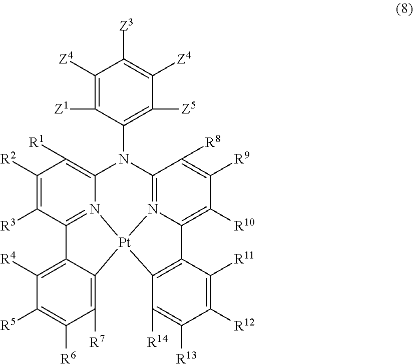

Likewise suitable are complexes of trivalent lanthanides, for example Tb³⁺ and Eu³⁺ (J. Kido et al. Appl. Phys. Lett. 65 (1994), 2124, Kido et al. Chem. Left. 657, 1990, US 2007/0252517 A1) or phosphorescent complexes of Pt(II), Ir(I), Rh(I) with maleonitrile dithiolate (Johnson et al., JACS 105, 1983, 1795), Re(I)-tricarbonyldiimine complexes (inter alia Wrighton, JACS 96, 1974, 998), Os(II) complexes with cyano ligands and bipyridyl or phenanthroline ligands (Ma et al., Synth. Metals 94, 1998, 245) or Alq₃.

Further phosphorescent emitters having tridentate ligands are described in U.S. Pat. No. 6,824,895 and U.S. Pat. No. 7,029,766. Red-emitting phosphorescent complexes are disclosed in U.S. Pat. No. 6,835,469 and U.S. Pat. No. 6,830,828.

Further particularly preferred phosphorescent emitters are compounds of the following formulae (9) and (10) and further compounds as disclosed, for example, in US 2001/0053462 A1 and WO 2007/095118 A1:

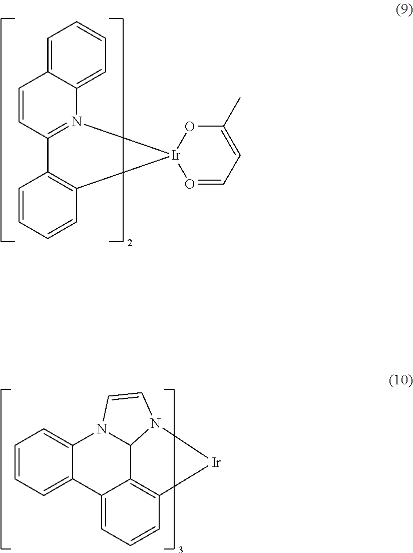

Further derivatives are disclosed in U.S. Pat. No. 7,378,162 B2, U.S. Pat. No. 6,835,469 B2 and JP 2003/253145 A.

Particular preference is given to an emitter in the emitter layer selected from the group of the organometallic complexes.

In addition to the metal complexes mentioned in this application, suitable metal complexes according to the present invention are selected from transition metals, rare earth elements, lanthanides and actinides. The metal is preferably selected from Ir, Ru, Os, Eu, Au, Pt, Cu, Zn, Mo, W, Rh, Pd and Ag.

The proportion of the emitter structural units in the polymer having hole-conducting or predominantly hole-conducting properties which is used in the emitter layer is preferably in the range from 0.01 to 20 mol %, more preferably in the range from 0.5 to 10 mol %, even more preferably in the range from 1 to 8 mol % and especially in the range from 1 to 5 mol %.

The hole-conducting properties of the copolymer used in the emitter layer are likewise achieved via the selection of suitable structural units. The polymer having the hole-conducting or predominantly hole-conducting properties contains at least one repeat unit selected from the group of the hole transport materials (HTM), preferably having at least one repeat unit which forms the polymer backbone.

According to the invention, it is possible to use any HTM known to those skilled in the art as repeat unit in the polymer having the hole-conducting or predominantly hole-conducting properties. Such an HTM is preferably selected from amines, triarylamines, thiophenes, carbazoles, phthalocyanines, porphyrins and isomers and derivatives thereof. The HTM is more preferably selected from amines, triarylamines, thiophenes, carbazoles, phthalocyanines and porphyrins.

Suitable repeat HTM units are phenylenediamine derivatives (U.S. Pat. No. 3,615,404), arylamine derivatives (U.S. Pat. No. 3,567,450), amino-substituted chalcone derivatives (U.S. Pat. No. 3,526,501), styrylanthracene derivatives (JP A 56-46234), polycyclic aromatic compounds (EP 1009041), polyarylalkane derivatives (U.S. Pat. No. 3,615,402), fluorenone derivatives (JP A 54-110837), hydrazone derivatives (U.S. Pat. No. 3,717,462), stilbene derivatives (JP A 61-210363), silazane derivatives (U.S. Pat. No. 4,950,950), polysilanes (JP A 2-204996), aniline copolymers (JP A 2-282263), thiophene oligomers, polythiophenes, polyvinylcarbazoles (PVKs), polypyrroles, polyanilines and further copolymers, porphyrin compounds (JP A 63-2956965), aromatic dimethylidene-like compounds, carbazole compounds, for example CDBP, CBP and mCP, aromatic tertiary amine and styrylamine compounds (U.S. Pat. No. 4,127,412), and monomeric triarylamines (U.S. Pat. No. 3,180,730). Preferably, triarylamine groups are present in the polymer.

Preference is given to aromatic tertiary amines containing at least two tertiary amines units (U.S. Pat. No. 4,720,432 and U.S. Pat. No. 5,061,569), for example 4,4′-bis[N-(1-naphthyl)-N-phenylamino]biphenyl (NPD) (U.S. Pat. No. 5,061,569) or MTDATA (JP A 4-308688), N,N,N′,N′-tetra(4-biphenyl)diaminobiphenylene (TBDB), 1,1-bis(4-di-p-tolylaminophenyl)cyclohexane (TAPC), 1,1-bis(4-di-p-tolylaminophenyl)-3-phenylpropane (TAPPP), 1,4-bis[2-[4-[N,N-di(p-tolyl)amino]phenyl]vinyl]benzene (BDTAPVB), N,N,N′,N′-tetra-p-tolyl-4,4′-diaminobiphenyl (TTB), TPD, N,N,N′,N′-tetraphenyl-4,4′″-diamino-1,1′:4′,1″:4″,1′″-quaterphenyl, and likewise tertiary amines containing carbazole units, for example 4-(9H-carbazol-9-yl)-N,N-bis[4-(9H-carbazol-9-yl)phenyl]benzenamine (TCTA). Preference is likewise given to hexaazatriphenylene compounds according to US 2007/0092755 A1.

Particular preference is given to the triarylamine compounds of the formulae (11) to (16) which follow, and which may also be substituted.

Compounds of this kind are disclosed in EP 1162193 A1, EP 650955 A1, in Synth. Metals 1997, 91(1-3), 209, in DE 19646119 A1, WO 2006/122630 A1, EP 1860097 A1, EP 1834945 A1, JP 08/053397 A, U.S. Pat. No. 6,251,531 B1 and WO 2009/041635.

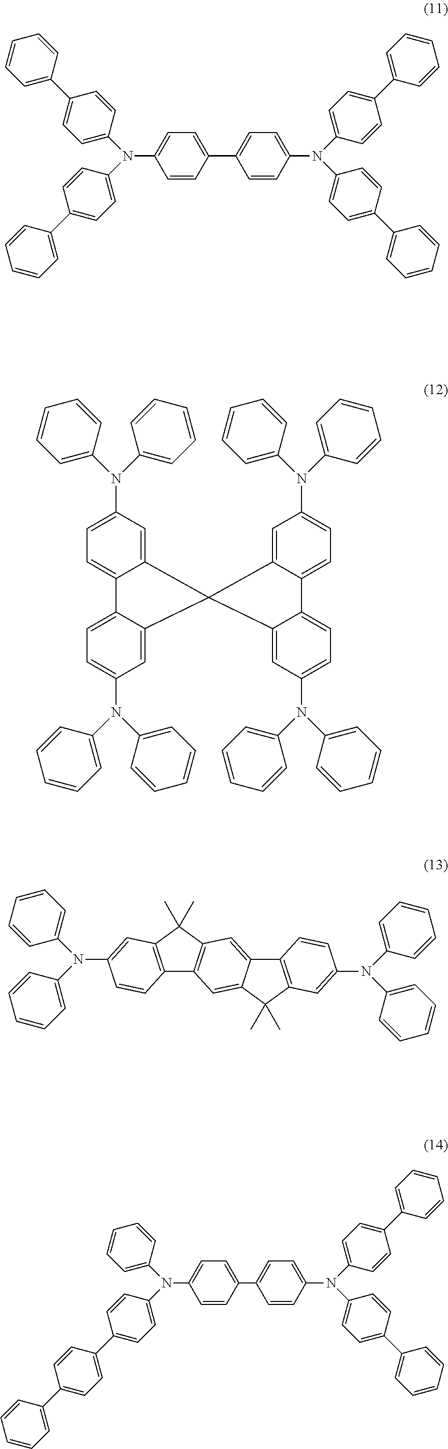 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; CC1(c2cc(N(c3ccccc3)c3ccccc3)ccc2-c2ccc(N(c3ccccc3)c3ccccc3)cc2)c2cc(N(c3ccccc3)c3ccccc3)ccc2-c2ccc(N(c3ccccc3)c3ccccc3)cc21 ; CC1(C)c2cc(N(c3ccccc3)c3ccccc3)ccc2-c2cc3c(cc21)-c1ccc(N(c2ccccc2)c2ccccc2)cc1C3(C)C ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

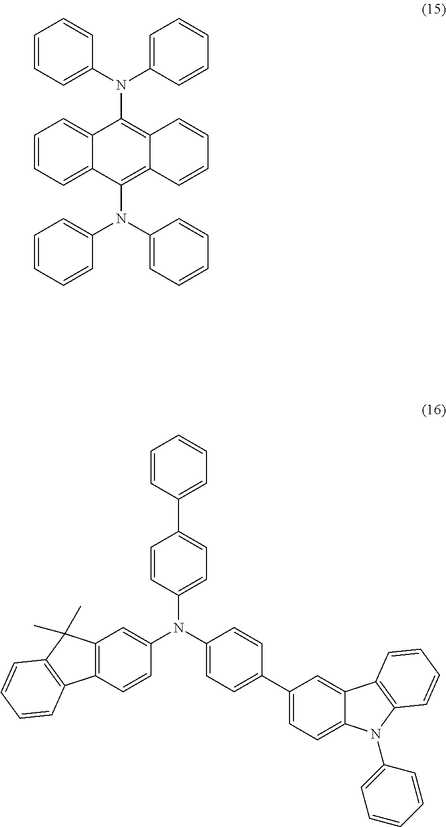

Further preferred HTM units are, for example, triarylamine, benzidine, tetraaryl-para-phenylenediamine, carbazole, azulene, thiophene, pyrrole and furan derivatives, and additionally O-, S- or N-containing heterocycles.

Very particular preference is given to repeat HTM units of the following formula (17):

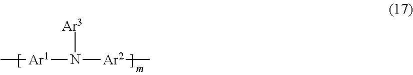

where

Ar¹, which may be the same or different, independently when in different repeat units, are a single bond or an optionally substituted monocyclic or polycyclic aryl group,

Ar², which may be the same or different, independently when in different repeat units, are an optionally substituted monocyclic or polycyclic aryl group,

Ar³, which may be the same or different, independently when in different repeat units, are an optionally substituted monocyclic or polycyclic aryl group, and

m is 1, 2 or 3.

Preferred repeat units of the formula (17) are selected from the following formulae (18) to (20):

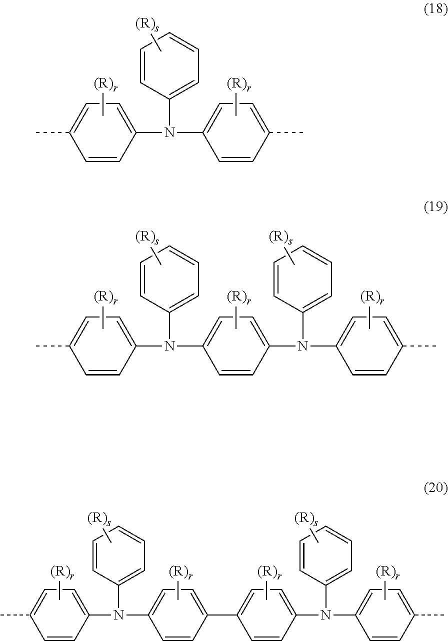

where

R, which may be the same or different at each instance, is selected from H, substituted or unsubstituted aromatic or heteroaromatic group, alkyl, cycloalkyl, alkoxy, aralkyl, aryloxy, arylthio, alkoxycarbonyl, silyl, carboxyl group, a halogen atom, cyano group, nitro group and hydroxyl group,

r is 0, 1, 2, 3 or 4 and

s is 0, 1, 2, 3, 4 or 5.

In a further preferred embodiment, the polymer having hole-conducting or predominantly hole-conducting properties contains at least one of the following repeat units of the formula (21):

-(T¹)_{c}-(Ar⁴)_{d}-(T²)ₑ-(Ar⁵)_{f} (21)

where

T¹ and T² are each independently selected from thiophene, selenophene, thieno[2,3b]thiophene, thieno[3,2b]thiophene, dithienothiophene, pyrrole, aniline, all optionally substituted by R⁵,

R⁵ independently at each instance is selected from halogen, —CN, —NC, —NCO, —NCS, —OCN, SCN, C(═O)NR⁰R⁰⁰, —C(═O)X, —C(═O)R⁰, —NH₂, —NR⁰R⁰⁰, SH, SR⁰, —SO₃H, —SO₂R⁰, —OH, —NO₂, —CF₃, —SF₅, optionally substituted silyl, or carbyl or hydrocarbyl which has 1 to 40 carbon atoms and is optionally substituted and optionally contains one or more heteroatoms,

Ar⁴ and Ar⁵ are independently monocyclic or polycyclic aryl or heteroaryl which is optionally substituted and optionally fused to the 2,3 positions of one or both of the adjacent thiophene or selenophene groups,

c and e are independently 0, 1, 2, 3 or 4, where 1<c+e≦6, and

d and f are independently 0, 1, 2, 3 or 4.

The T¹ and T² groups are preferably selected from

| | |
|---|---|
| 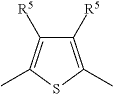 | thiophene-2,5-diyl, |
| 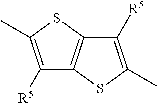 | thieno[3,2-b]thiophene-2,5- diyl, |
| 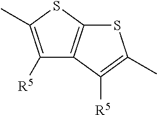 | thieno[2,3-b]thiophene-2,5- diyl, |
| 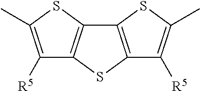 | dithienothiophene-2,6-diyl and |
| 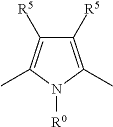 | pyrrole-2,5-diyl, |

where

R⁰ and R⁵ may assume the same definition as for R in the formulae (18) to (20).

Preferred units of the formula (21) are selected from the group consisting of the following formulae:

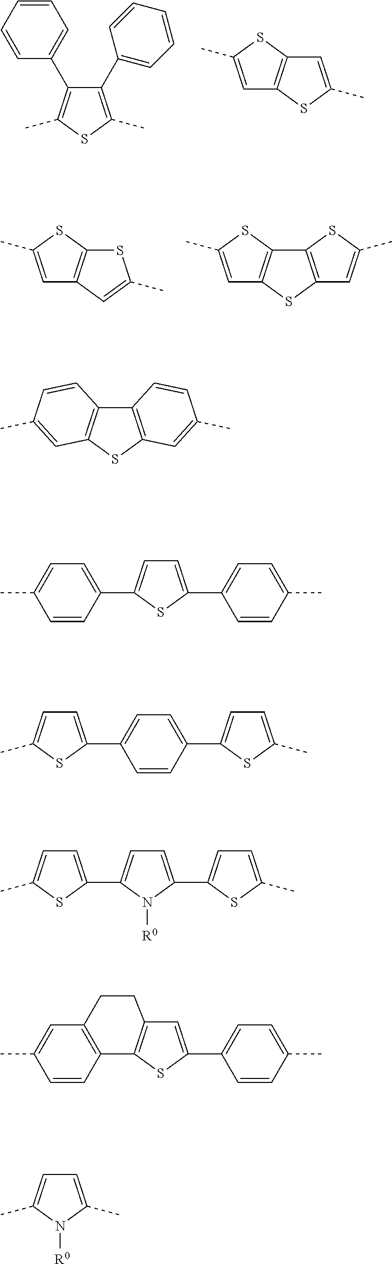

where

R⁰ may assume the same definition as for R in the formulae (18) to (20).

The proportion of the HTM structural units in the hole-conducting or predominantly hole-conducting polymer which is used in the emitter layer is preferably in the range from 10 to 99 mol %, more preferably in the range from 20 to 80 mol % and most preferably in the range from 30 to 60 mol %.

As well as the hole-conducting structural units, the polymer used in the emitter layer preferably also has further structural units which form the backbone of the polymer.

Preferably, the structural units which form the polymer backbone contain aromatic or heteroaromatic structures having 6 to 40 carbon atoms. These are, for example, 4,5-dihydropyrene derivatives, 4,5,9,10-tetrahydropyrene derivatives, fluorene derivatives as disclosed, for example, in U.S. Pat. No. 5,962,631, WO 2006/052457 A2 and WO 2006/118345 A1, 9,9′-spirobifluorene derivatives as disclosed, for example, in WO 2003/020790 A1, 9,10-phenanthrene derivatives as disclosed, for example, in WO 2005/104264 A1, 9,10-dihydrophenanthrene derivatives as disclosed, for example, in WO 2005/014689 A2, 5,7-dihydrodibenzoxepine derivatives and cis- and trans-indenofluorene derivatives as disclosed, for example, in WO 2004/041901 A1 and WO 2004/113412 A2, and binaphthylene derivatives as disclosed, for example, in WO 2006/063852 A1, and additionally units, as disclosed, for example, in WO 2005/056633 A1, EP 1344788 A1, WO 2007/043495 A1, WO 2005/033174 A1, WO 2003/099901 A1 and DE 102006003710.

Particularly preferred structural units which form the polymer backbone are selected from fluorene as disclosed, for example, in U.S. Pat. No. 5,962,631, WO 2006/052457 A2 and WO 2006/118345 A1, spirobifluorene as disclosed, for example, in WO 2003/020790 A1, benzofluorene, dibenzofluorene and benzothiophene, and derivatives thereof, as disclosed, for example, in WO 2005/056633 A1, EP 1344788 A1 and WO 2007/043495 A1.

Very particularly preferred structural units which form the polymer backbone are units of the following formula (22):

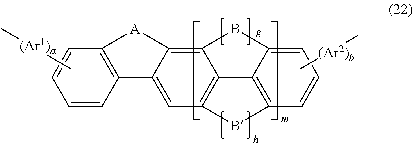

where

A, B and B′ are independently, and independently at each instance, a divalent group, preferably selected from —CR¹R²—, —NR¹—, —PR¹—, —O—, —S—, —SO—, —SO₂—, —CO—, —CS—, —CSe—, —P(═O)R¹—, —P(═S)R¹— and —SiR¹R²—,

R¹ and R² are independently identical or different groups selected from H, halogen, —CN, —NC, —NCO, —NCS, —OCN, SCN, C(═O)NR⁰R⁰⁰, —C(═O)X, —C(═O)R⁰, —NH₂, —NR⁰R⁰⁰, SH, SR⁰, —SO₃H, —SO₂R⁰⁰, —OH, —NO₂, —CF₃, —SF₅, optionally substituted silyl, or carbyl or hydrocarbyl which has 1 to 40 carbon atoms and is optionally substituted and optionally contains one or more heteroatoms, and the R¹ and R² groups optionally form a spiro group together with the fluorene moiety to which they are bonded,

X is halogen,

R⁰ and R⁰⁰ are independently H or an optionally substituted carbyl or hydrocarbyl group optionally containing one or more heteroatoms,

each g is independently 0 or 1 and the respective corresponding h in the same subunit is the other of 0 and 1,

m is an integer Z 1,

Ar¹ and Ar² are independently mono- or polycyclic aryl or heteroaryl which is optionally substituted and optionally fused to the 7,8 positions or 8,9 positions of the indenofluorene group, and

a and b are independently 0 or 1.

If the R¹ and R² groups together with the fluorene group to which they are bonded form a spiro group, the structure is preferably a spirobifluorene.

The structural units of the formula (22) are preferably selected from the following formulae (23) to (27):

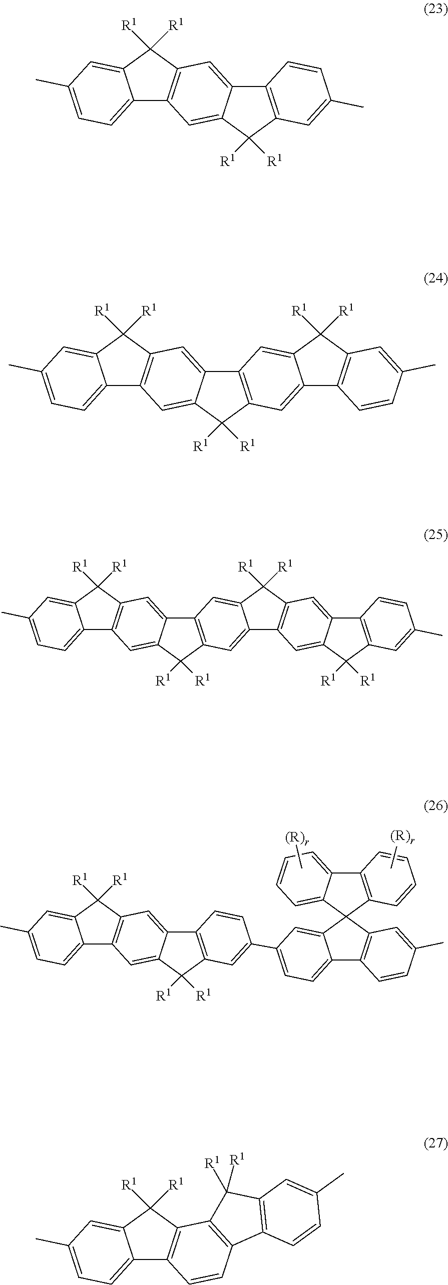

where R¹ is as defined in formula (22), r is 0, 1, 2, 3 or 4 and R may assume one of the definitions of R¹.

Preferably, R is F, Cl, Br, I, —CN, —NO₂, —NCO, —NCS, —OCN, SCN, —C(═O)NR⁰R⁰⁰, —C(═O)Xo, —C(═O)R⁰, —NR⁰R⁰⁰, optionally substituted silyl, aryl or heteroaryl having 4 to 40 and preferably 6 to 20 carbon atoms, or straight-chain, branched or cyclic alkyl, alkoxy, alkylcarbonyl, alkoxycarbonyl, alkylcarbonyloxy or alkoxycarbonyloxy having 1 to 20 and preferably 1 to 12 carbon atoms, in which one or more hydrogen atoms are optionally replaced by F or Cl and in which R⁰, R⁰⁰ and X⁰ are as defined above.

Particularly preferred structural units of the formula (22) are selected from the following formulae (28) to (31):

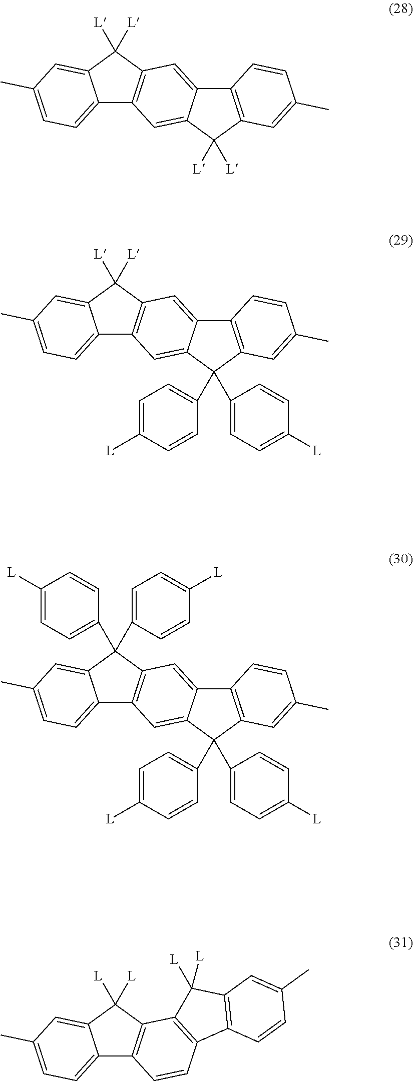

where

L is H, halogen or optionally fluorinated linear or branched alkyl or alkoxy having 1 to 12 carbon atoms and preferably H, F, methyl, i-propyl, t-butyl, n-pentoxy or trifluoromethyl, and

L′ is optionally fluorinated linear or branched alkyl or alkoxy having 1 to 12 carbon atoms and preferably n-octyl or n-octyloxy.

In a preferred embodiment of the present invention, the polymer in the emitter layer is a conjugated polymer having at least one emitting structural unit, at least one hole-transporting structural unit and at least one structural unit which forms the polymer backbone.

In the present application, “conjugated polymers” are understood to mean polymers having mainly carbon atoms having sp² hybridization and/or optionally having sp hybridization in the main chain, where some of the carbon atoms may be replaced by heteroatoms. The simplest case of this involves a main chain having alternating single and double (or triple) carbon bonds, or main chains composed of phenylene radicals. “Mainly” in this connection means that polymers in which the conjugation in the main chain is interrupted by defects that occur are also included. Conjugated polymers may have heteroatom-containing units in the main chain, for example arylamines, arylphosphines or heterocycles in which the conjugation is partly via nitrogen, oxygen, phosphorus or sulfur atoms, or organometallic complexes in which the conjugation is partly via metal atoms. Conjugated polymers should thus be understood in the broadest sense. These may, for example, be random polymers, block polymers or graft polymers.

Very particularly preferred structural units which form the polymer backbone are selected from fluorene, spirobifluorene, indenofluorene, phenanthrene, dihydrophenanthrene, dibenzothiophene, dibenzofuran and derivatives thereof.

Examples of conjugated polymers containing hole-transporting units are disclosed in WO 2007/131582 A1 and WO 2008/009343 A1.

Examples of conjugated polymers containing metal complexes and synthesis methods therefor are disclosed in EP 1138746 B1 and DE102004032527A1.

In a further preferred embodiment of the present invention, the polymer in the emitter layer is a non-conjugated or partly conjugated polymer.

More preferably, the non-conjugated or partly conjugated polymer in the interlayer contains a non-conjugated polymer backbone structural unit.

This non-conjugated polymer backbone structural unit is preferably selected from indenofluorene structural units of the following formulae (32) and (33) as disclosed, for example, in WO 2010/136110 A1:

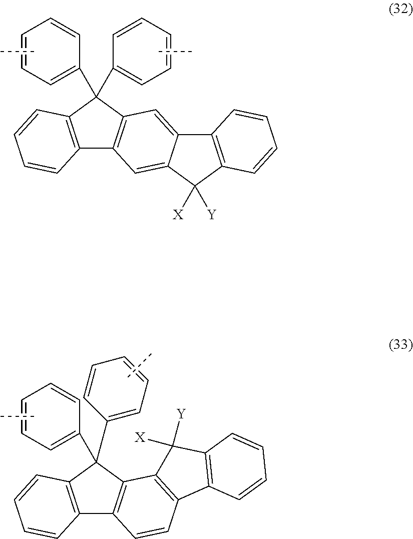

where

X and Y are independently selected from the group consisting of H, F, a C₁₋₄₀-alkyl group, a C₂₋₄₀-alkenyl group, a C₂₋₄₀-alkynyl group, an optionally substituted C₆₋₄₀-aryl group and an optionally substituted 5- to 25-membered heteroaryl group.

Further preferred non-conjugated polymer backbone structural units are selected from fluorene, phenanthrene, dihydrophenanthrene and indenofluorene derivatives of the following formulae (34a) to (37d), as disclosed, for example, in WO 2010/136111 A1:

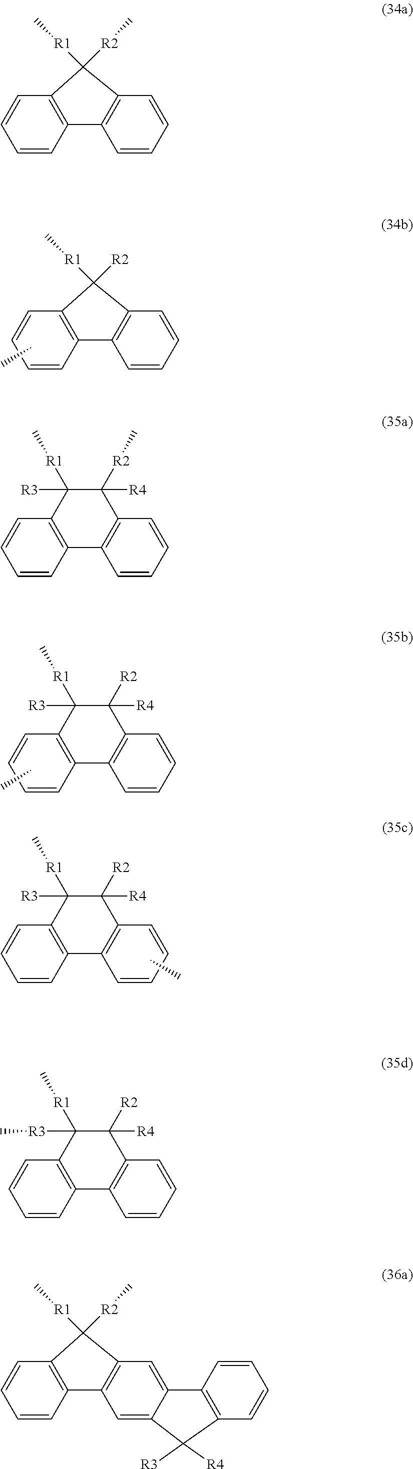

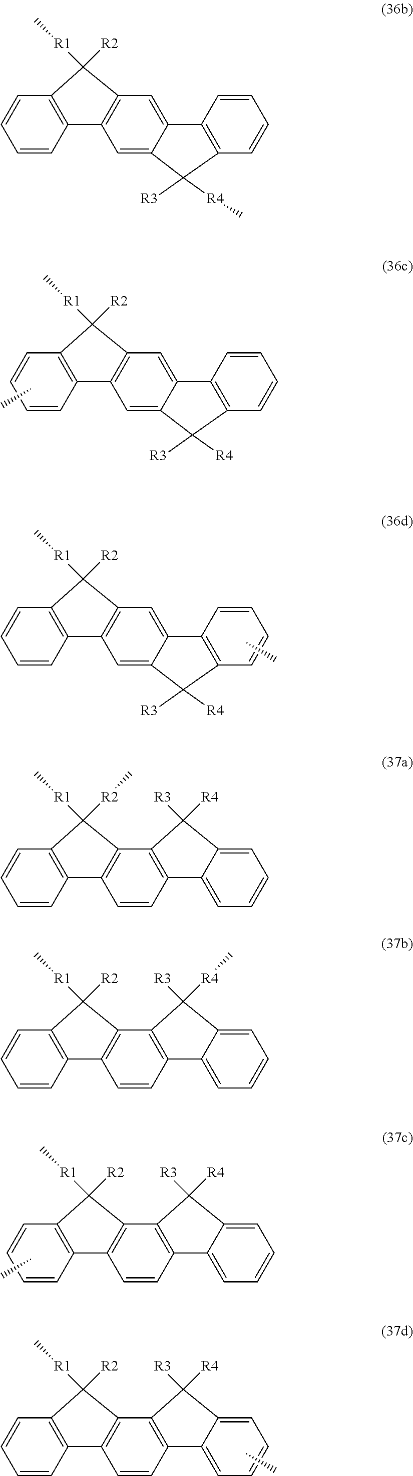

where R1 to R4 may assume the same definitions as X and Y in the formulae (32) and (33).

The proportion of the structural units that form the polymer backbone in the hole-conducting or predominantly hole-conducting polymer which is used in the emitter layer is preferably in the range from 10 to 99 mol %, more preferably in the range from 20 to 80 mol % and most preferably in the range from 30 to 60 mol %.

The electronic device of the present invention has an electron-transporting layer (ETL) having electron-conducting or predominantly electron-conducting properties. This property can be achieved by using a suitable electron transport material in an appropriate concentration in the ETL layer.

According to the invention, any electron transport material (ETM) known to those skilled in the art may be used either as low molecular weight compound or preferably as repeat unit in a polymer in the electron-transporting layer. Suitable ETMs are preferably selected from imidazoles, pyridines, pyrimidines, pyridazines, pyrazines, oxadiazoles, quinolines, quinoxalines, anthracenes, benzanthracenes, pyrenes, perylenes, benzimidazoles, triazines, ketones, phosphine oxides, phenazines, phenanthrolines, triarylboranes and the isomers and derivatives thereof.

Suitable ETM structural units are metal chelates of 8-hydroxyquinoline (e.g. Liq, Alq₃, Gaq₃, Mgq₂, Znq₂, Inq₃, Zrq₄), Balq, 4-azaphenanthren-5-ol/Be complexes (U.S. Pat. No. 5,529,853 A; e.g. formula 7), butadiene derivatives (U.S. Pat. No. 4,356,429), heterocyclic optical brighteners (U.S. Pat. No. 4,539,507), benzazoles, for example 1,3,5-tris(2-N-phenylbenzimidazolyl)benzene (TPBI) (U.S. Pat. No. 5,766,779, formula 8), 1,3,5-triazine derivatives (U.S. Pat. No. 6,229,012 B1, U.S. Pat. No. 6,225,467 B1, DE 10312675 A1, WO 98/04007A1 and U.S. Pat. No. 6,352,791 B1), pyrenes, anthracenes, tetracenes, fluorenes, spirobifluorenes, dendrimers, tetracenes, e.g. rubrene derivatives, 1,10-phenanthroline derivatives (JP 2003/115387, JP 2004/311184, JP 2001/267080, WO 2002/043449), silacylcyclopentadiene derivatives (EP 1480280, EP 1478032, EP 1469533), pyridine derivatives (JP 2004/200162 Kodak), phenanthrolines, e.g. BCP and Bphen, and a number of phenanthrolines bonded via biphenyl or other aromatic groups (US 2007/0252517 A1) or anthracene-bonded phenanthrolines (US 2007/0122656 A1, e.g. formulae 9 and 10), 1,3,4-oxadiazoles, e.g. formula 11, triazoles, e.g. formula 12, triarylboranes, benzimidazole derivatives and other N-heterocyclic compounds (see US 2007/0273272 A1), silacyclopentadiene derivatives, borane derivatives, Ga-oxinoid complexes.

A preferred ETM structural unit is selected from a unit of the formula (38) having a C═X group in which X=O, S or Se, preferably O, as disclosed, for example, in WO 2004/093207 A2 and WO 2004/013080 A1.

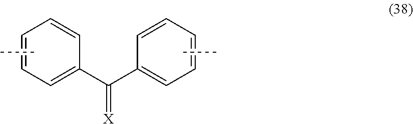

More preferably, the structural units of the formula (38) have fluorene ketones, spirobifluorene ketones or indenofluorene ketones of the formulae (38a), (38b) and (38c):

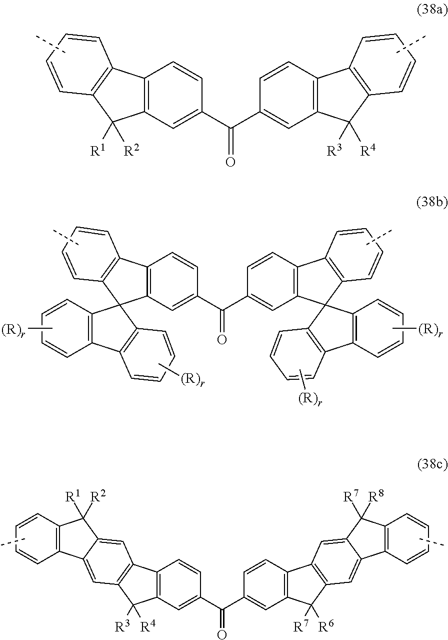

where

R and R¹⁻⁸ are each independently a hydrogen atom, a substituted or unsubstituted aromatic cyclic hydrocarbyl group having 6 to 50 carbon atoms in the ring, a substituted or unsubstituted aromatic heterocyclic group having 5 to 50 ring atoms, a substituted or unsubstituted alkyl group having 1 to 50 carbon atoms, a substituted or unsubstituted cycloalkyl group having 3 to 50 carbon atoms in the ring, a substituted or unsubstituted alkoxy group having 1 to 50 carbon atoms, a substituted or unsubstituted aralkyl group having 6 to 50 carbon atoms in the ring, a substituted or unsubstituted aryloxy group having 5 to 50 carbon atoms in the ring, a substituted or unsubstituted arylthio group having 5 to 50 carbon atoms in the ring, a substituted or unsubstituted alkoxycarbonyl group having 1 to 50 carbon atoms, a substituted or unsubstituted silyl group having 1 to 50 carbon atoms, carboxyl group, a halogen atom, a cyano group, nitro group or hydroxyl group. One or more of the R¹ and R², R³ and R⁴, R⁵ and R⁶, R⁷ and R⁸ pairs optionally form a ring system, and

r is 0, 1, 2, 3 or 4.

Further preferred ETM structural units are selected from the group consisting of imidazole derivatives and benzimidazole derivatives of the formula (39), as disclosed, for example, in US 2007/0104977 A1.

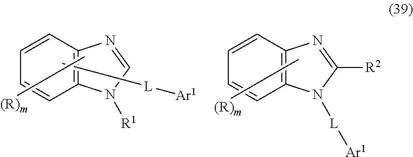

where

R is a hydrogen atom, a C6-C60-aryl group which may have a substituent, a pyridyl group which may have a substituent, a quinolyl group which may have a substituent, a C1-20 alkyl group which may have a substituent, or a C1-20-alkoxy group which may have a substituent;

m is an integer from 0 to 4;

R¹ is a C6-60-aryl group which may have a substituent, a pyridyl group which may have a substituent, a quinolyl group which may have a substituent, a C1-20 alkyl group which may have a substituent, or a C1-20-alkoxy group which may have a substituent;

R² is a hydrogen atom, a C6-60-aryl group which may have a substituent, a pyridyl group which may have a substituent, a quinolyl group which may have a substituent, a C1-20 alkyl group which may have a substituent, or a C1-20-alkoxy group which may have a substituent; and

L is a C6-60-arylene group which may have a substituent, a pyridinylene group which may have a substituent, a quinolinylene group which may have a substituent, or a fluorenylene group which may have a substituent, and Ar¹ is a C6-60-aryl group which may have a substituent, a pyridinyl group which may have a substituent, or a quinolinyl group which may have a substituent.

Preference is further given to 2,9,10-substituted anthracenes (by 1- or 2-naphthyl and 4- or 3-biphenyl) or molecules containing two anthracene units as disclosed, for example, in US 2008/0193796 A1.

In a further preferred embodiment, the ETM materials are selected from heteroaromatic ring systems of the following formulae (40) to (45):

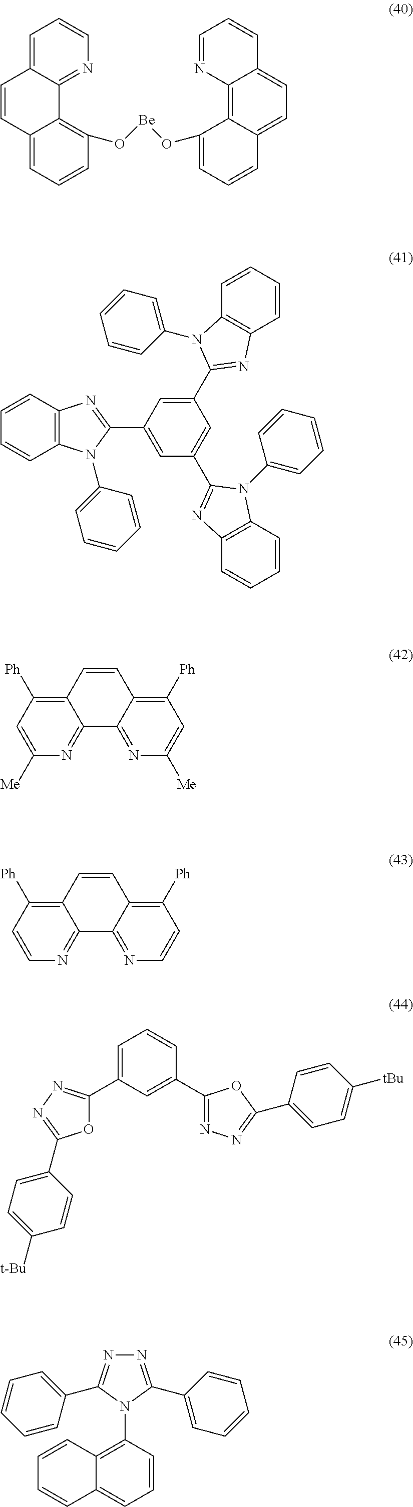

Particular preference is given to anthracenebenzimidazole derivatives of the formulae (46) to (48) as disclosed, for example, in U.S. Pat. No. 6,878,469 B2, US 2006/147747 A and EP 1551206 A1:

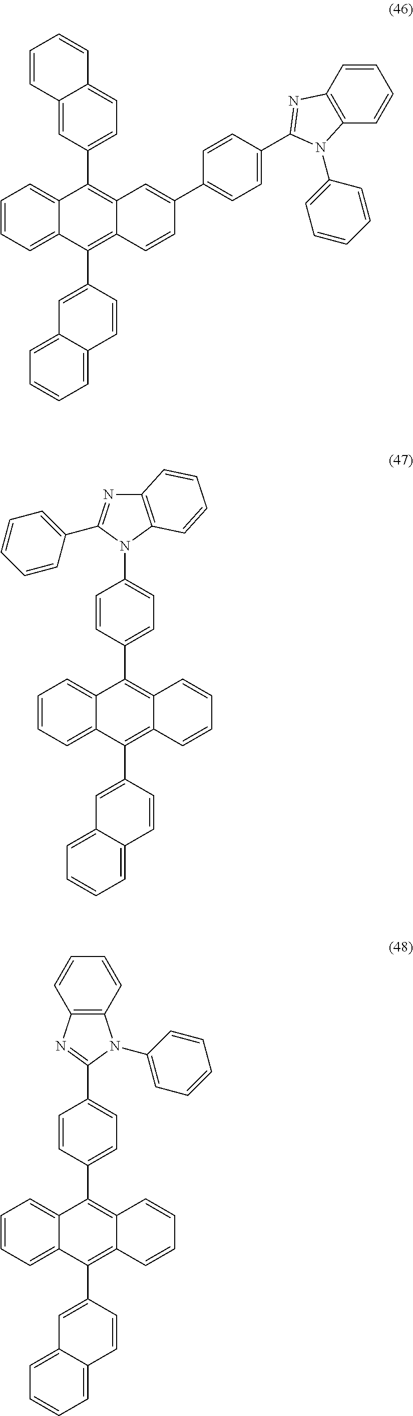 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2nc3ccccc3n2-c2ccc(-c3c4ccccc4c(-c4ccc5ccccc5c4)c4ccccc34)cc2)cc1 ; c1ccc(-n2c(-c3ccc(-c4c5ccccc5c(-c5ccc6ccccc6c5)c5ccccc45)cc3)nc3ccccc32)cc1]

Copolymers used with particular preference for the electron transport layer contain structural units having electron-conducting properties which derive from benzophenone, triazine, imidazole or benzimidazole derivatives, or perylene units which may optionally be substituted. Examples of these are benzophenone units, aryltriazine units, benzimidazole units and diarylperylene units.

Particular preference is given to using structural units or compounds having electron-conducting properties selected from the structural units of the following formulae (49) to (52):

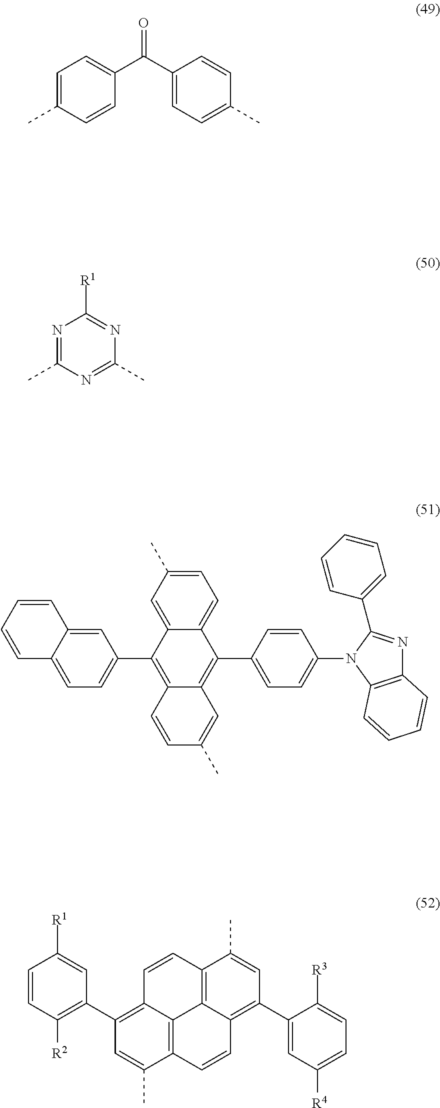

where

R¹ to R⁴ may assume the same definitions as R in formula (38).

The proportion of materials having electron-conducting properties or the proportion of structural units having electron-conducting properties in the polymer in the electron-transporting layer having electron-conducting or predominantly electron-conducting properties is preferably in the range from 10 to 99 mol %, more preferably in the range from 20 to 80 mol % and most preferably in the range from 30 to 60 mol %.

In a preferred embodiment, the electron-conducting material is incorporated into a polymer as structural unit, and is thus an electron-conducting polymer.

Preferably, the electron-conducting polymer has at least one further structural unit selected from polymer backbone structural units as described above in relation to the polymers in the emitter layer.

The proportion of the at least one polymer backbone structural unit in the electron-conducting polymer is preferably in the range from 10 to 99 mol %, more preferably in the range from 20 to 80 mol % and most preferably in the range from 30 to 60 mol %.

Very particularly preferred structural units which form the polymer backbone in the electron-conducting polymer are selected from fluorene, spirobifluorene, indenofluorene, phenanthrene, dihydrophenanthrene, dibenzothiophene and dibenzofuran, and derivatives thereof.

In a preferred embodiment, the electron-conducting polymer is a conjugated polymer. Particularly preferred polymer backbone structural units of the conjugated polymer are selected from the abovementioned structural units of the formulae (23) to (31).

In a further preferred embodiment of the present invention, the electron-conducting polymer is a non-conjugated or partly conjugated polymer.

Particularly preferred polymer backbone structural units of the non-conjugated or partly conjugated polymer are selected from the abovementioned structural units of the formulae (32) to (37d).

In a further preferred embodiment, the electron-conducting layer comprises exclusively low molecular weight electron transport materials as described above.

In a further preferred embodiment, the electron-conducting layer comprises a mixture of at least one low molecular weight electron transport material and a polymer. Particularly preferred polymer backbone structural units of this polymer are selected from fluorene, spirobifluorene, indenofluorene, phenanthrene and dihydrophenanthrene, and derivatives thereof. In addition, this polymer may also additionally have electron-conducting repeat units as described above.

Examples of polymers containing an electron-conducting structural unit and the corresponding syntheses are disclosed for triazine units as electron-conducting structural units, for example, in US 2003/0170490 A1.

The present application further provides formulations comprising the hole-conducting or predominantly hole-conducting polymer and at least one solvent.

The electronic device of the invention may additionally comprise further layers which may be selected from hole injection layer, emitter layer, electron blocker layer, hole blocker layer, exciton-generating layer and electron injection layer inter alia.

Preferably, the at least one emitter layer of the device of the invention is applied from solution.

In a particularly preferred embodiment, both layers, the at least one emitter layer and the at least one electron transport layer of the electroluminescent device of the invention, are applied from solution.

A preferred embodiment of the electroluminescent device of the invention has the structure described hereinafter, which is especially advantageous for top emission displays:
a substrate, typically composed of glass or plastic, or the reverse side of an AM display,
a cathode, with general use here of metals, combinations of metals or metal alloys having a low work function, for example Ca, Ba, Cs, Mg, Al, In or Mg/Ag,
optionally an electron injection layer (EIL), where this layer may optionally be combined with the HBL and/or ETL layers mentioned hereinafter,
at least one electron transport layer (ETL) which is intended firstly to transport electrons and secondly to block holes,
at least one emitter layer composed of the above-described material (EML),
optionally a hole injection layer (HIL), and
a transparent anode, typically composed of indium tin oxide (“ITO”).

In a preferred embodiment, an air-stable cathode is used in the electroluminescent device of the invention. Air-stable cathodes of this kind may consist of TiO₂, as reported by Haque et al., in Adv. Mater. 2007, 19, 683-687, or of ZrO₂, as reported by Bradley et al. in Adv. Mater. DOI: 10.1002/adma.200802594, or of ZnO, as reported by Bolink et al. in Adv. Mater. 2009, 21, 79-82.

The present application further provides electroluminescent polymers having hole-conducting or predominantly hole-conducting properties, as already described above in relation to the at least one emitter layer of the electroluminescent device of the invention.

Preferably, the polymer having hole-conducting or predominantly hole-conducting properties has at least one hole-transporting structural unit and at least one emitting structural unit, where the at least one hole-transporting structural unit and the at least one emitting structural unit may be selected from the structural units already described above in relation to the emitting polymers for the at least one emitter layer of the electroluminescent device of the invention.

More preferably, the material of the invention having hole-conducting or predominantly hole-conducting properties additionally has at least one polymer backbone structural unit which may be selected from the polymer backbone structural units already described above.

Very particular preference is given to selecting the structural units which form the polymer backbone from fluorene, spirobifluorene, indenofluorene, phenanthrene, dihydrophenanthrene, dibenzothiophene, dibenzofuran and derivatives thereof.

Most preferably, the hole-transporting structural units are selected from amines, triarylamines, thiophenes, carbazoles and the abovementioned structural units of the formulae (18) to (21).

Examples of hole-transporting polymers are disclosed in WO 2007/131582 A1 and WO 2008/009343 A1.

Examples of polymers containing metal complexes and the synthesis methods therefor are disclosed in EP 1138746 B1 and DE 102004032527 A1.

In a further preferred embodiment, the polymer of the invention is a non-conjugated or partly conjugated polymer.

A particularly preferred non-conjugated or partly conjugated polymer of the invention contains a non-conjugated polymer backbone structural unit.

The non-conjugated polymer backbone structural unit is preferably selected from the above-described indenofluorene structural units of the formulae (32) and (33).

Further preferred non-conjugated polymer backbone structural units are selected from the above-described fluorene, phenanthrene, dihydrophenanthrene and indenofluorene derivatives of the formulae (34a) to (37d).

The proportion of the polymer backbone structural units in the polymer of the invention having hole-conducting or predominantly hole-conducting properties is preferably in the range from 10 to 99 mol %, more preferably in the range from 20 to 80 mol % and most preferably in the range from 30 to 60 mol %.

The proportion of the hole-transporting structural units in the polymer of the invention having hole-conducting or predominantly hole-conducting properties is preferably in the range from 10 to 99 mol %, more preferably in the range from 20 to 80 mol % and most preferably in the range from 30 to 60 mol %.

The proportion of the emitting structural units in the polymer of the invention having hole-conducting or predominantly hole-conducting properties is preferably in the range from 0.01 to 20 mol %, more preferably in the range from 0.5 to 10 mol % and most preferably in the range from 1 to 5 mol %.

The present application also provides a mixture comprising at least one polymer of the invention having hole-conducting or predominantly hole-conducting properties, as described above.

The present application further provides a formulation comprising at least one polymer of the invention having hole-conducting or predominantly hole-conducting properties, as described above, and at least one solvent.

In a preferred embodiment, the formulation is a homogeneous solution, meaning that only one homogeneous phase exists.

In a further embodiment, the formulation is an emulsion, meaning that both a continuous phase and a discontinuous phase exist.

Preferably, the at least one solvent is selected from the group of the organic solvents. More preferably, the organic solvent is selected from dichloromethane, trichloromethane, monochlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 1,1,1-trichloroethane, 1,1,2,2-tetrachloroethane, ethyl acetate, n-butyl acetate, dimethylformamide, dimethylacetamide, dimethyl sulfoxide, tetralin, decalin, indane and mixtures thereof.

The concentration of the polymer of the invention in the formulation is preferably in the range from 0.001% to 50% by weight, more preferably in the range from 0.01% to 20% by weight, even more preferably in the range from 0.1% to 10% by weight and especially in the range from 0.1% to 5% by weight. The formulation may optionally additionally comprise at least one binder in order to be able to adjust the rheological properties, as described, for example, in WO 2005/055248 A1.

The present application also provides for the use of the polymer of the invention having hole-conducting or predominantly hole-conducting properties, or of a mixture comprising the polymer of the invention having hole-conducting or predominantly hole-conducting properties, in electronic devices.

The present application likewise provides an electronic device comprising the polymer of the invention having hole-conducting or predominantly hole-conducting properties.

The electronic device preferably has 2, 3, 4, 5 or 6 electrodes.

In a particularly preferred embodiment, the electronic device has two electrodes: an anode and a cathode.

The electronic device of the invention can be used to emit light, to collect light or to detect light. The present application thus provides electronic devices which emit light (photodiodes), which collect light (solar cells) and/or which detect light (sensors).

Preferably, the electronic device is selected from organic light-emitting diodes (OLEDs), polymeric light-emitting diodes (PLEDs), organic light-emitting electrochemical cells, organic field-effect transistors (OFETs), thin-film transistors (TFTs), organic solar cells (O-SCs), organic laser diodes (O-lasers), organic integrated circuits (O-ICs), RFID (radio frequency identification) tags, photodetectors, sensors, logic circuits, memory elements, capacitors, charge injection layers, Schottky diodes, planarization layers, antistatic films, conductive substrates or pattems, photoconductors, electrophotographic elements, organic light-emitting transistors (OLETs), organic spintronic devices and organic plasmon-emitting devices (OPEDs).

Organic plasmon-emitting devices (OPEDs), as described by Koller et al., in Nature Photonics 2008, 2, 684-687, are similar to OLEDs, except that at least one of the electrodes should be capable of interacting with the surface plasmons of the emitting layer. Preferably, an OPED comprises a nano-diamondoid or a polymer of the invention having hole-conducting or predominantly hole-conducting properties.

An electrophotographic element comprises a substrate, an electrode and a charge transport layer atop the electrode, and optionally a charge generation layer between the electrode and the charge transport layer. For details in relation to the device and possible variations and the materials used therein, reference is made to the appropriate literature (Organic Photoreceptors for Xerography, Marcel Dekker, Inc., ed. by Paul M. Borsenberger & D. S. Weiss (1998)). Preferably, such a device comprises a nano-diamondoid or a polymer of the invention having hole-conducting or predominantly hole-conducting properties, more preferably in the charge transport layer.

A preferred organic spintronic device is what is called a “spin-valve” device, as described by Z. H. Xiong et al., in Nature 2004, vol. 427, 821, comprising two ferromagnetic electrodes and at least one organic layer between the two ferromagnetic electrodes, at least one of the organic layers comprising a polymer of the invention having hole-conducting or predominantly hole-conducting properties. The ferromagnetic electrode is composed of Co, Ni, Fe or an alloy thereof, or of ReMnO3 or CrO2, where Re is a rare earth element.

Organic light-emitting electrochemical cells (OLECs) contain two electrodes, and a mixture or blend of an electrolyte and a fluorescent species in between, as first described by Pei & Heeger in Science 1995, 269, 1086-1088. Preference is given to using nano-diamondoids or polymers of the invention having hole-conducting or predominantly hole-conducting properties in such devices.

Dye solar cells, also called dye-sensitized solar cells (DSSCs), contain a working electrode, a thin nanoporous layer of titanium dioxide (TiO₂), a thin layer of a light-sensitive dye, the electrolyte and the counterelectrode, as first described by O'Regan & Gratzel in Nature 1991, 353, 737-740. The liquid electrolyte may be replaced by a solid hole transport layer, as described, for example, in Nature 1998, 395, 583-585.

More preferably, the electronic device of the invention is an organic light-emitting diode (OLED).

OLEDs typically have the following layer structure:
optionally a first substrate,
an anode,
optionally a hole injection layer (HIL),
optionally a hole transport layer (HTL) and/or an electron blocker layer (EBL),
an active layer which produces excitons on electrical or optical excitation,
optionally an electron transport layer (ETL) and/or a hole blocker layer (HBL),
optionally an electron injection layer (EIL),
optionally a layer comprising at least one nano-diamondoid and optionally at least one organic functional material,
a cathode, and
optionally a second substrate.

The sequence of the above layer structure is illustrative. Other layer sequences are possible. Depending on the active layer in the above-described structure, different electronic devices may be obtained.

In a first preferred embodiment, in the active layer, electrical excitation by application of a voltage between the anode and the cathode generates excitons which emit light through radiative decay. This is a light-emitting device.

In a further embodiment, in the active layer, absorption of light generates excitons and free charge transport is produced through dissociation of the excitons. This is a photovoltaic cell or a solar cell.

The examples which follow are intended to illustrate the invention in detail without restricting it. More particularly, the features, properties and advantages that are described therein for the defined compounds that form the basis of the example in question are also applicable to other compounds that are not referred to in detail but are covered by the scope of protection of the claims, unless the opposite is stated elsewhere.

### WORKING EXAMPLES

### A) Preparation of the Polymers

The two polymers which follow are prepared by Suzuki coupling, as described in WO 03/048225.

### Example 1

Polymer 1 is a copolymer having essentially hole transport properties and having the following composition:

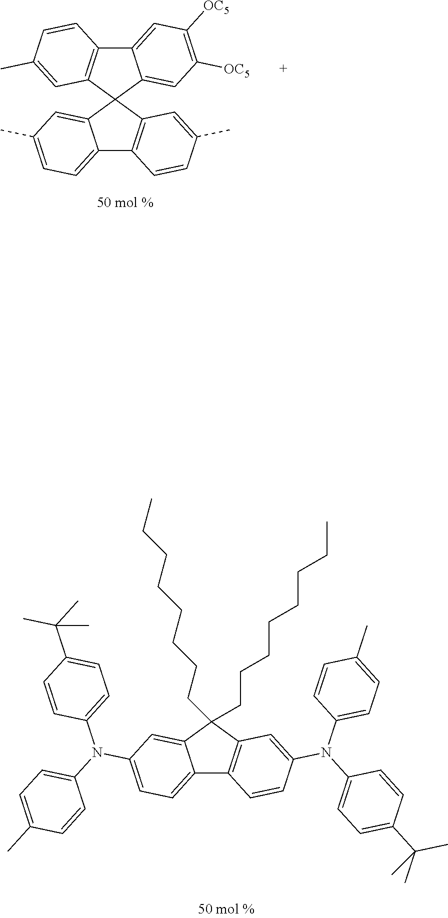

### Example 2

Polymer 2 is a copolymer having essentially electron transport properties and having the following composition:

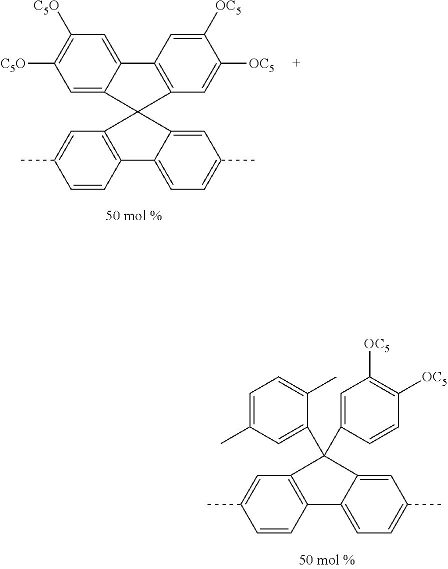

### B) Production of the OLEDs

### Comparative Example 3

### Production of OLED 1

OLED 1 is a one-layer device in which polymer 1 is used as emitter in the emitter layer. OLED 1 is produced as follows:
1) Deposition of an 80 nm-thick PEDOT layer (Baytron P Al 4083) onto a glass substrate coated with indium tin oxide by spin-coating.
2) Deposition of a 60 nm-thick layer of polymer 1 by spin-coating from a toluene solution having a polymer concentration of 1% by weight.
3) Baking of the device at 180° C. under inert gas for 10 minutes.
4) Deposition of a cathode (8 nm Ba/150 nm Ag) by vacuum evaporation on the emitter layer.
5) Encapsulation of the device.

### Example 4

### Production of OLED 2

OLED 2 is a two-layer device in which polymer 1 is used as emitter in the emitter layer and polymer 2 is used as electron transport material in the electron transport layer. OLED 2 is produced as follows:
1) Deposition of an 80 nm-thick PEDOT layer (Baytron P Al 4083) onto a glass substrate coated with indium tin oxide by spin-coating.
2) Deposition of a 20 nm-thick layer of polymer 1 by spin-coating from a toluene solution having a polymer concentration of 1% by weight.
3) Baking of the device at 180° C. under inert gas for 60 minutes.
4) Deposition of a 60 nm-thick layer of polymer 2 by spin-coating from a toluene solution having a polymer concentration of 1% by weight.
5) Baking of the device at 180° C. under inert gas for 10 minutes.
6) Deposition of a cathode (8 nm Ba/150 nm Ag) by vacuum evaporation on the emitter layer.
7) Encapsulation of the device.

### Comparative Example 5

### Production of OLED 3

OLED 3 is a one-layer device in which polymer 2 is used as emitter in the emitter layer. The production steps for production of OLED 3 are the same as for the production of OLED 1, except that polymer 2 is used in place of polymer 1 in step 2.

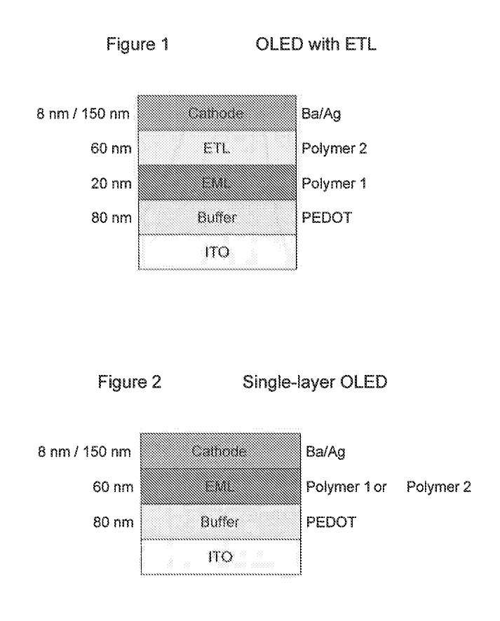

The OLED devices OLED 1 and OLED 3 produced have the structure shown in FIG. 2, and the OLED device OLED 2 of the invention has the structure shown in FIG. 1.

### C) Characterization of the OLEDs

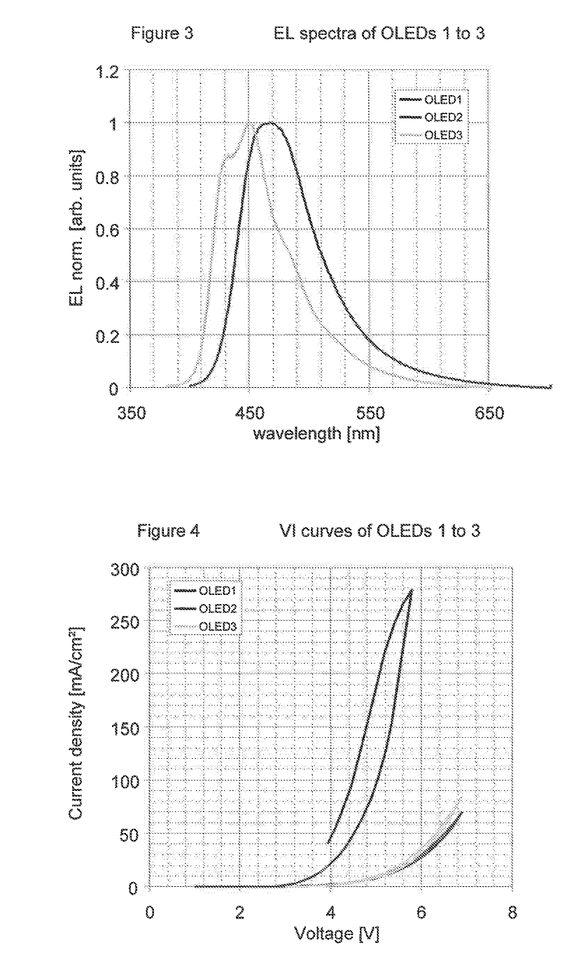

FIG. 3 shows the EL spectra of the three OLEDs 1 to 3. As FIG. 3 shows, the spectra of the OLED 1 and OLED 2 are virtually identical, which demonstrates that the emission in the two OLEDs comes from the predominantly hole-conducting polymer P1.

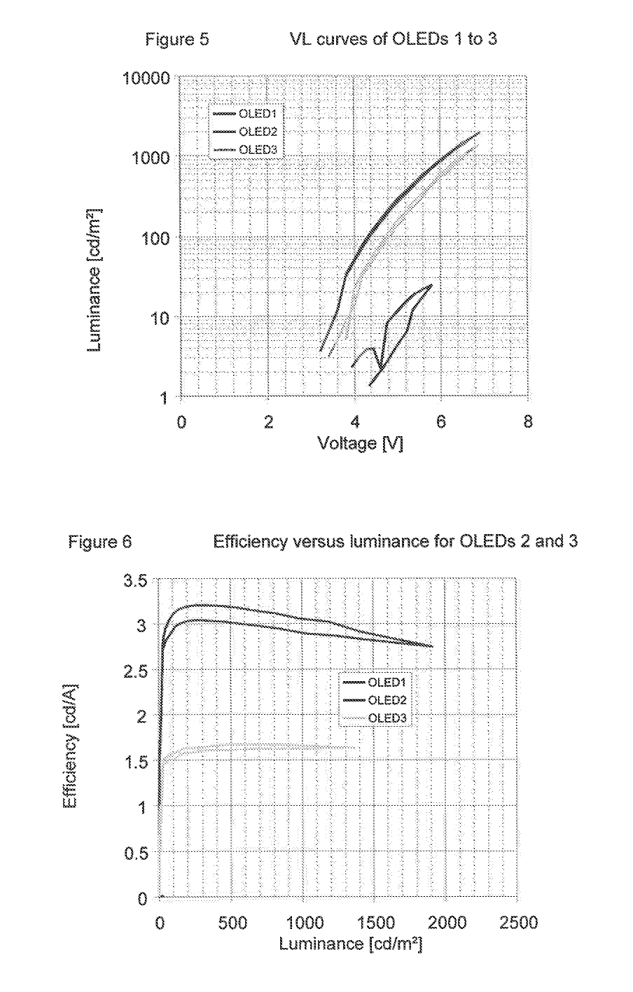

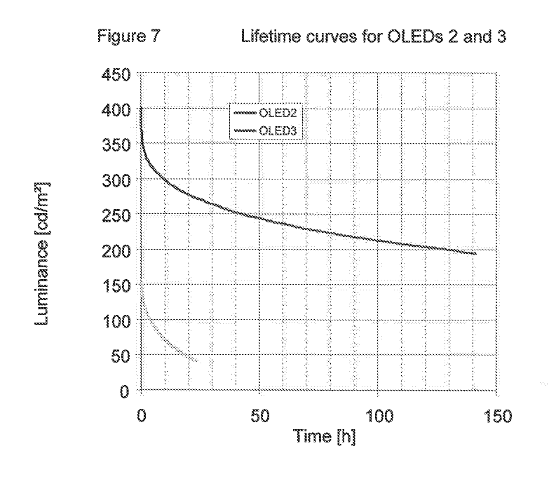

The properties of the three OLEDs produced are summarized in table 1. As table 1 shows, the use of the predominantly hole-conducting polymer 1 in the emitter layer and of the predominantly electron-conducting polymer 2 in the electron transport layer leads to a distinct improvement in all the properties measured, compared to the one-layer devices of OLEDs 1 and 3. The essential properties of the three OLEDs are additionally shown in FIGS. 4 to 7.

As FIG. 4 shows, the “hole current” in OLED 1 is very high, meaning that the holes reach the cathode without recombining with the electrons beforehand. For this reason, the efficiency of this OLED is very low and hence determination of the lifetime is impossible.

As the above results have shown, it is surprisingly possible to achieve electroluminescent devices having excellent properties with the polymer of the invention having hole-conducting or predominantly hole-conducting properties.

TABLE 1
Properties of OLEDs 1, 2 and 3

| | Max. eff. | Uon | U(100) | CIE @ | LT DC | |
|---|---|---|---|---|---|---|
| Device | [cd/A] | [V] | [V] | 100 cd/m² | [hrs @ nits] | |
| OLED 1 | 0.0 | 4.5 | — | 0.16/0.22 | — | — |
| OLED 2 | 3.1 | 2.8 | 3.7 | 0.16/0.21 | 130 | 400 |
| OLED 3 | 1.7 | 3.3 | 4.9 | 0.16/0.11 | 11 | 139 |

1-18. (canceled)

19. An electroluminescent device comprising
a) an anode;
b) a cathode;
c) at least one emitter layer which comprises at least one emitter and is disposed between the anode and the cathode; and
d) at least one electron transport layer which comprises at least one material having electron-conducting or predominantly electron-conducting properties and is disposed between the at least one emitter layer and the cathode;
wherein the at least one emitter layer comprises a polymer having hole-conducting or predominantly hole-conducting properties.

20. The electroluminescent device of claim 19, wherein the at least one emitter is incorporated as a repeat unit into the polymer having hole-conducting or predominantly hole-conducting properties.

21. The electroluminescent device of claim 19, wherein the emitter is selected from the group consisting of fluorescent and phosphorescent compounds.

22. The electroluminescent device of claim 21, wherein the emitter is a phosphorescent metal complex, wherein the metal is selected from the group consisting of transition metals, rare earth elements, lanthanides. and actinides, and is preferably selected from Ir, Ru, Os, Eu, Au, Pt, Cu, Zn, Mo, W, Rh, Pd and Ag.

23. The electroluminescent device of claim 22, wherein the metal is selected from the group consisting of Ir, Ru, Os, Eu, Au, Pt, Cu, Zn, Mo, W, Rh, Pd, and Ag.

24. The electroluminescent device of claim 19, wherein the polymer having hole conducting or predominantly hole-conducting properties comprises at least one repeat unit selected from amines, triarylamines, thiophenes, carbazoles, phthalocyanines, porphyrins, and the isomers and derivatives thereof.

25. The electroluminescent device of claim 24, wherein the polymer having hole conducting or predominantly hole-conducting properties comprises at least one amine repeat unit selected from the group consisting of repeat units of formulae (18) to (20): 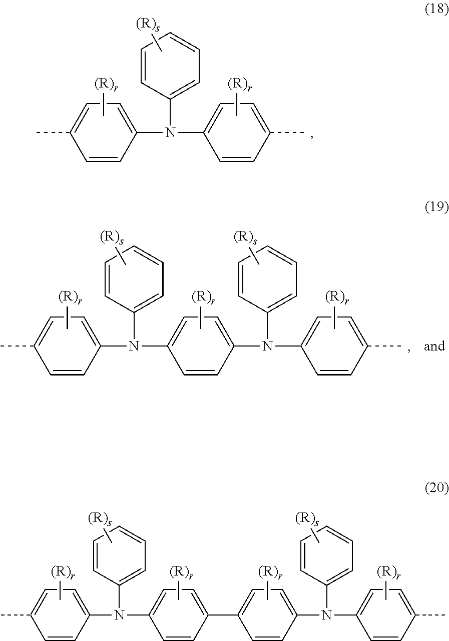
wherein
R may be the same or different in each instance and is selected from the group consisting of H, substituted or unsubstituted aromatic or heteroaromatic groups, alkyl groups, cycloalkyl groups, alkoxy groups, aralkyl groups, aryloxy groups, arylthio groups, alkoxycarbonyl groups, silyl groups, carboxyl groups, halogen atoms, cyano groups, nitro groups, and hydroxyl groups;
r is 0, 1, 2, 3, or 4; and
s is 0, 1, 2, 3, 4, or 5.

26. The electroluminescent device of claim 19, wherein the polymer having hole-conducting or predominantly hole-conducting properties further comprises structural units which form the backbone of the polymer.

27. The electroluminescent device of claim 26, wherein the further structural units which form the backbone of the polymer are selected from the group consisting of fluorene, spirobifluorene, indenofluorene, phenanthrene, dihydrophenanthrene, dibenzothiophene, dibenzofuran, and derivatives thereof.

28. The electroluminescent device of claim 19, wherein the polymer having hole-conducting or predominantly hole-conducting properties is a conjugated polymer.

29. The electroluminescent device of claim 19, wherein the polymer having hole-conducting or predominantly hole-conducting properties is a non-conjugated or partly conjugated polymer.

30. The electroluminescent device of claim 29, wherein the non-conjugated or partly conjugated polymer comprises indenofluorene structural units selected from the group consisting of structural units of formulae (32) and (33): 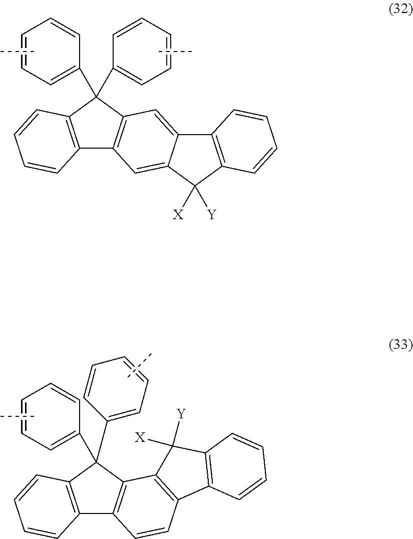
wherein
X and Y are independently selected from the group consisting of H, F, C₁₋₄₀-alkyl groups, C₂₋₄₀-alkenyl groups, C₂₋₄₀-alkynyl groups, optionally substituted C₆₋₄₀-aryl groups, and optionally substituted 5- to 25-membered heteroaryl groups.

31. The electroluminescent device of claim 19, wherein the at least one material having electron-conducting or predominantly electron-conducting properties in the electron transport layer is incorporated as a repeat unit into a polymer in the electron transport layer.

32. A polymer having hole-conducting or predominantly hole-conducting properties, wherein it has at least one hole-conducting structural unit and at least one emitting structural unit.

33. The polymer of claim 32, wherein the polymer is a conjugated polymer.

34. A formulation comprising at least one polymer of claim 32 and at least one organic solvent.

35. An electronic device comprising a polymer of claim 32.

36. The electronic device of claim 35, wherein the electronic device is selected from the group consisting of organic light-emitting diodes, polymeric light-emitting diodes, organic light-emitting electrochemical cells, organic field-effect transistors, thin-film transistors, organic solar cells, organic laser diodes, organic integrated circuits, radio frequency identification tags, photodetectors, sensors, logic circuits, memory elements, capacitors, charge injection layers, Schottky diodes, planarization layers, antistatic films, conductive substrates, conductive patterns, photoconductors, electrophotographic elements, organic light-emitting transistors, organic spintronic devices, and organic plasmon-emitting devices, preferably from organic light-emitting diodes (OLEDs).

37. The electronic device of claim 36, wherein the electronic device is an organic light-emitting diode.
